(19) United States
(12) Patent Application Publication
(10) Pub. No.: US 2026/0049244 A1
(43) Pub. Date: Feb. 19, 2026

(54) LIGHT-EMITTING ELEMENT, DISPLAY DEVICE, AND METHOD FOR PRODUCING LIGHT-EMITTING ELEMENT

(71) Applicant: Sharp Display Technology Corporation, Kameyama City, Mie (JP)

(72) Inventor: YUSUKE SAKAKIBARA, Sakai City, Osaka (JP)

(21) Appl. No.: 19/103,800

(22) PCT Filed: Sep. 22, 2022
(86) PCT No.: PCT/JP2022/035516

§ 371 Date: Feb. 13, 2025

(51) Int. Cl. C09K 11/88; B82Y 20/00; B82Y 40/00; C09K 11/02; C09K 11/08; C09K 11/71; H10K 50/115; H10K 71/12; H10K 101/00

(52) U.S. Cl. CPC C09K 11/885; C09K 11/025; C09K 11/0883; C09K 11/71; C09K 11/883; H10K 50/115; H10K 71/12; B82Y 20/00; B82Y 40/00; H10K 2101/80

(57) ABSTRACT

A light-emitting element includes: a first electrode; a second electrode; and a quantum-dot layer; provided between the first electrode and the second electrode. The quantum-dot layer contains a plurality of quantum dots including at least cores, and an inorganic filler material filling spaces between the plurality of quantum dots. At least a portion of a composition of the quantum-dot layer around at least one core has a concentration gradient in a direction from toward a center of the core to toward around the core.

### TECHNICAL FIELD

The present disclosure relates to a light-emitting element containing quantum dots serving as a light-emitting material, a display device including a plurality of the light-emitting elements, and a method for producing the light-emitting elements.

### BACKGROUND ART

Patent Document 1 discloses a quantum-dot light-emitting layer included in a light-emitting element. The quantum-dot light-emitting layer has a first surface in contact with a hole transport layer and a second surface in contact with an electron transport layer. The first surface and the second surface have organic ligands distributed in different manners, thereby decreasing a voltage of the light-emitting element.

### CITATION LIST

### Patent Literature

[Patent Document 1] Japanese Unexamined Patent Application Publication No. 2010-114079

### SUMMARY

### Technical Problems

As to the light-emitting element described in Patent Document 1, each of the plurality of quantum dots contained in the quantum-dot light-emitting layer is covered either with first organic ligands or with the first organic ligands and second organic ligands. Hence, the quantum-dot light-emitting layer of the light-emitting element disclosed in Patent Document 1 fails to reduce creation of excessive organic ligands. Here, in the quantum-dot light-emitting layer, the influence of the excessive organic ligands causes an increase in reactive current. As a result, the light-emitting element suffers a decrease in external quantum efficiency (EQE).

Furthermore, in the quantum-dot light-emitting layer described in Patent Document 1, each of the ligands is an organic ligand. Hence, the organic ligand deteriorates because of energization or penetration of such foreign substance as water. As a result, the quantum-dot light-emitting layer suffers a decrease in reliability.

### Solution to Problems

A light-emitting element according to an embodiment of the present disclosure includes: a first electrode; a second electrode; and a quantum-dot layer positioned between the first electrode and the second electrode, and containing a plurality of quantum dots including at least cores, and an inorganic filler material filling spaces between the plurality of quantum dots, at least a portion of a composition of the quantum-dot layer around at least one of the cores having a concentration gradient in a direction from toward a center of the at least one core to toward around the core.

A method, for producing a light-emitting element including: a first electrode; a second electrode; and a quantum-dot layer positioned between the first electrode and the second electrode, and containing a plurality of quantum dots including at least cores, and an inorganic filler material filling spaces between the plurality of quantum dots, includes: a synthesizing step of synthesizing the quantum dots; a forming step of forming the quantum-dot layer containing the inorganic filler material and the quantum dots synthesized at the synthesizing step; and at least one of a first step of synthesizing the quantum dots at the synthesizing step, the quantum dots each including one of the cores and a shell positioned partially around the one core, and at least a portion of a composition of the shell having a concentration gradient from toward a center of the core to toward around the core, or a second step of forming the quantum-dot layer at the forming step, at least a portion of a composition of the inorganic filler material having a concentration gradient from toward the center of at least one of the cores to toward around the core.

### Advantageous Effect of Disclosure

A light-emitting element is provided to contain quantum dots that operate on a low voltage and improve in EQE and reliability.

### BRIEF DESCRIPTION OF DRAWINGS

FIG. 1 illustrates a schematic sectional side view of a display device according to a first embodiment, an enlarged schematic view in the vicinity of a quantum dot in the sectional side view, and a schematic view of an inorganic filler material to fill a space between quantum dots.

FIG. 2 illustrates a schematic plan view of the display device according to the first embodiment.

FIG. 3 illustrates other enlarged schematic views in the vicinity of the quantum dots in the sectional side view of the display device according to the first embodiment.

FIG. 4 illustrates a band diagram showing an example of a bandgap of each of the portions of a quantum-dot layer according to the first embodiment.

FIG. 5 is a flowchart showing an example of a method for producing the display device according to the first embodiment.

FIG. 6 illustrates a schematic sectional side view of a display device according to a second embodiment.

FIG. 7 illustrates an enlarged schematic view of a quantum-dot layer in the sectional side view of the display device according to the second embodiment, and enlarged schematic views in the vicinity of quantum dots.

FIG. 8 illustrates band diagrams each showing an exemplary bandgap of each of the portions of a quantum-dot layer according to the second embodiment.

FIG. 9 illustrates band diagrams each showing a bandgap of each of the portions of a quantum-dot layer according to the second embodiment.

### DESCRIPTION OF EMBODIMENTS

### First Embodiment

### Overview of Display Device

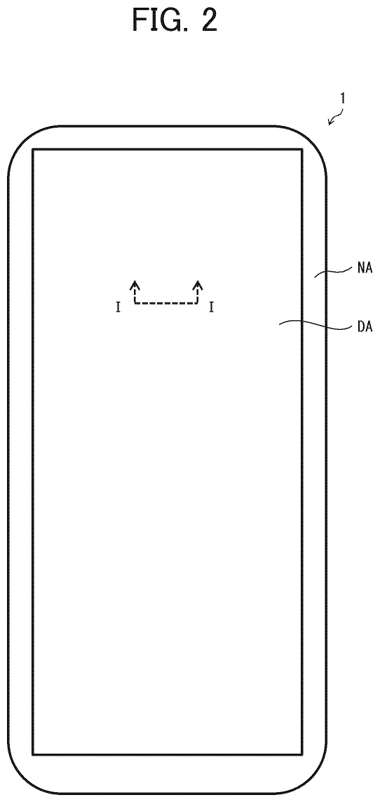

FIG. 2 illustrates a schematic plan view of a display device 1 according to this embodiment. The display device 1 includes: a display unit DA; and a picture-frame unit NA formed around an outer periphery of the display portion DA. The display device 1 controls light emitted from each of a plurality of light-emitting elements formed in the display unit DA. Hence, the display device 1 displays an image on the display unit DA. The light-emitting elements will be described later. The picture-frame unit NA may have such a unit as a driver formed to drive each of the plurality of light-emitting elements in the display unit DA.

### Overview of Substrate and Light-Emitting-Element Layer

The display unit DA of the display device 1 according to this embodiment includes a plurality of red subpixels, a plurality of green subpixels, and a plurality of blue subpixels. In a red subpixel, a red light-emitting element is formed. In a green subpixel, a green light-emitting element is formed. In a blue subpixel, a blue light-emitting element is formed. The red light-emitting element, the green light-emitting element, and the blue light-emitting element respectively emit a red light, a green light, and a blue light. The display device 1 individually controls the plurality of light-emitting elements in the display unit DA, using, for example, such a unit as a driver formed in the picture-frame unit NA. Hence, the display device 1 displays a color image.

Note that, in this embodiment, the blue light has a center wavelength in a wavelength band of, for example, 380 nm or more and 500 nm or less. Furthermore, the green light has a center wavelength in a wavelength band of, for example, more than 500 nm and 600 nm or less. Moreover, the red light has a center wavelength in a wavelength band of more than 600 nm and 780 nm or less.

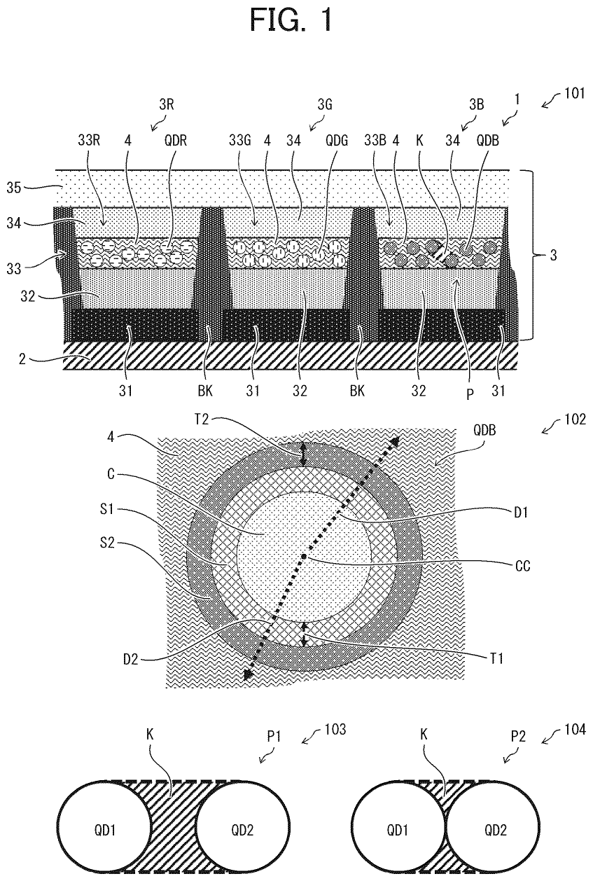

Described below in more detail with reference to FIG. 1 will be a structure of the display unit DA of the display device 1 according to this embodiment. FIG. 1 illustrates a schematic sectional side view 101 of the display device 1 according to this embodiment, an enlarged schematic view 102 in the vicinity of a quantum dot in the sectional side view, and schematic views 103 and 104 of an inorganic filler material to fill a space between quantum dots. The quantum dots will be described later.

The schematic sectional side view 101 of FIG. 1 is a cross-sectional view taken along arrows I-I in FIG. 2. In particular, the schematic sectional side view 101 is a cross-section of a plane perpendicular to an upper surface of the display unit DA and passing through a red light-emitting element 3R, a green light-emitting element 3G, and a blue light-emitting element 3B. The light-emitting elements will be described later. Hereinafter, in the Description, any of the schematic sectional side views of display devices show a cross-section in the same position as the cross-section in the schematic sectional side view 101 of FIG. 1.

The enlarged schematic view 102 of FIG. 1 shows the vicinity of a blue quantum dot QDB among quantum dots illustrated in the schematic sectional side view 101. The blue quantum dot QDB will be described later. The enlarged schematic view 102 shows a cross-section of a plane passing through a center CC of a core C of the blue quantum dot QDB.

The schematic view 103 and the schematic view 104 of FIG. 1 show two examples of a pair P of two blue quantum dots QDB and a region (a space) K between the two blue quantum dots QDB. Each of the blue quantum dots is illustrated in the enlarged schematic view 102 of the display device 1. In particular, the schematic view 103 and the schematic view 104 respectively show a pair P1 and a pair P2, each of which is an exemplary pair of a quantum dot QD1 and a quantum dot QD2.

The display device 1 includes in the display unit DA: a substrate 2 such as a glass substrate or a film substrate; and a light-emitting-element layer 3 above the substrate 2. The light-emitting-element layer 3 includes: an anode 31 serving as a first electrode; a hole transport layer 32; a quantum-dot layer 33; an electron transport layer 34; and a cathode 35 serving as a second electrode, all of which are provided in the stated order from toward the substrate 2 to toward the upper surface of the display unit DA.

In the light-emitting-element layer 3, the anode 31, the hole transport layer 32, a red quantum-dot layer 33R, the electron transport layer 34, and the cathode 35, all of which overlap with the red subpixel in a plan view of the substrate 2, form the red light-emitting element 3R. Furthermore, in the light-emitting-element layer 3, the anode 31, the hole transport layer 32, a green quantum-dot layer 33G, the electron transport layer 34, and the cathode 35, all of which overlap with the green subpixel in a plan view of the substrate 2, form the green light-emitting element 3G. Moreover, in the light-emitting-element layer 3, the anode 31, the hole transport layer 32, a blue quantum-dot layer 33B, the electron transport layer 34, and the cathode 35, all of which overlap with the blue subpixel in a plan view of the substrate 2, form the blue light-emitting element 3B.

Furthermore, the display device 1 includes a bank BK. The bank BK may be an insulating layer capable of either absorbing or blocking visible light. Examples of a material of the bank BK include a photosensitive resin containing a light-absorbing agent such as carbon black. Examples of the photosensitive resin include photosensitive organic insulating materials such as polyimide and acrylic resin. The bank BK partitions the plurality of light-emitting elements included in the display device 1. The bank BK is formed above the substrate 2, in particular, between a plurality of the anodes 31 in a plan view of the substrate 2. In this embodiment, the hole transport layer 32, the quantum-dot layer 33, and the electron transport layer 34 are partitioned with the bank BK for each of the subpixels. Note that the cathode 35 is formed in common to the plurality of subpixels.

The bank BK may be formed in a position overlapping with an end portion of each anode 31 in the plan view of the substrate 2. In this case, the bank BK can reduce an influence, of electric field concentration at the end portion of the anode 31 in each light-emitting element, on injection of holes from the anode 31 into the quantum-dot layer 33.

The anode 31 and the cathode 35 are electrodes containing a conductive material, and respectively and electrically connected to the hole transport layer 32 and the electron transport layer 34. When a voltage is applied to at least one of the anode 31 or the cathode 35, the holes are injected from the anode 31 into the hole transport layer 32 and the electrons are injected from the cathode 35 into the electron transport layer 34.

In this embodiment, each of the anodes 31 may be electrically connected to a not-shown pixel circuit formed on the substrate 2 for a corresponding one of the subpixels. The display device 1 may individually drive each of the pixel circuits to control a voltage to be applied to each of the anodes 31. For example, the display device 1 may apply a predetermined voltage to the cathode 35 and drive a voltage to be applied to each anode 31, so as to control light to be emitted from each of the light-emitting elements.

At least one of the anode 31 or the cathode 35 is a transparent electrode that transmits visible light. The transparent electrode may be formed of, for example, ITO, IZO, SnO₂, or FTO. Furthermore, at least one of the anode 31 or the cathode 35 may be a reflective electrode. The reflective electrode may contain a metal material highly reflective to visible light. The metal material may be either a single-component metal such as, for example, Al, Ag, Cu, or Au, or an alloy of these metals.

The hole transport layer 32 transports the holes, which are injected from the anode 31, to the quantum-dot layer 33. The hole transport layer 32 may be made of an organic or an inorganic material capable of transporting the holes and used for light-emitting elements containing quantum dots. Examples of the hole-transporting material include poly[(9,9-dioctylfluorenyl-2,7-diyl)-co-(4,4′-(N-(4-sec-butylphenyl))diphenylamine)] (abbreviated as “TFB”), poly[N,N′-bis(4-butylphenyl)-N,N′-bis(phenyl)-benzidine] (abbreviated as “p-TPD”), and polyvinyl carbazole (abbreviated as “PVK”). These hole-transporting materials may be used alone or in combination of two or more. In addition, a not-shown hole injection layer may be formed. Examples of the hole-injecting material include a composite (abbreviated as “PEDOT: PSS”) containing poly(3,4-ethylenedioxythiophene) (PEDOT) and polystyrene sulphonate (PSS), nickel oxide (NiO), and copper thiocyanate (CuSCN). Note that these materials may be used alone or in combination of two or more as appropriate. The electron transport layer 34 transports the electrons, which are injected from the cathode 35, to the quantum-dot layer 33. The electron transport layer 34 may be made of an organic or an inorganic material capable of transporting the electrons and used for light-emitting elements containing quantum dots. Examples of the electron-transporting material include zinc oxide (ZnO) nanoparticles, zinc magnesium oxide (MgZnO) nanoparticles, and 2,2′,2″-(1,3,5,-benzinetriyl)-tris(1-phenyl-1-H-benzimidazole) (abbreviated as “TPBi”). These electron-transporting materials may be used alone, or in combination of two or more as appropriate.

### Quantum Dots

The quantum-dot layer 33 includes: the red quantum-dot layer 33R, the green quantum-dot layer 33G, and the blue-quantum-dot layer 33B. In the plan view of the substrate 2, the red quantum-dot layer 33R, the green quantum-dot layer 33G, and the blue quantum-dot layer 33B are formed in positions respectively overlapping with the red subpixel, the green subpixel, and the blue subpixel.

The red quantum-dot layer 33R, the green quantum-dot layer 33G, and the blue quantum-dot layer 33B respectively contain, as quantum dots, a plurality of red quantum dots QDR, a plurality of green quantum dots QDG, and a plurality of blue quantum dots QDB. When each of the light-emitting elements is driven, the holes are injected from the anode 31 through the hole transport layer 32 into each of the quantum dots, and the electrons are injected from the cathode 35 through the electron transport layer 34 into each of the quantum dots.

The red quantum dots QDR, the green quantum dots QDG, and the blue quantum dots QDB each include at least a core. Injected into the core of each quantum dot are holes from the anode 31 and electrons from the cathode 35. When the holes and the electrons recombine together, excitons are generated to emit light. The red quantum dots QDR, the green quantum dots QDG, and the blue quantum dots QDB emit a red light, a green light, and a blue light from the respective cores.

Note that, in the present disclosure, the “quantum dots” are dots each having a maximum width of 100 nm or less. A quantum dot may have any given shape as long as the maximum width of the quantum dot is within the above range. The shape of the quantum dot shall not be limited to a spherical shape (a circular cross-section). The quantum dot may have, for example, a polygonal cross-section, a bar-like three dimensional shape, a branch-like three dimensional shape, or a three dimensional shape having asperities on the surface. Alternatively, the quantum dot may have a combination of those shapes.

The quantum dots may be typically made of a semiconductor. The semiconductor may have a certain bandgap. The semiconductor may be any given material capable of emitting light, and may include at least materials to be described below. The semiconductor may be capable of emitting a red light, a green light, and a blue light. The semiconductor includes at least one selected from the group consisting of, for example, a group II-VI compound, a group III-V compound, a chalcogenide, and a perovskite compound. Note that the group II-VI compound means a compound containing a group II element and a group VI element, and the group III-V compound means a compound containing a group III element and a group V element. Moreover, the group II element may include a group 2 element and a group 12 element, the group III element may include a group 3 element and a group 13 element, the group V element may include a group 5 element and a group 15 element, and the group VI element may include a group 6 element and a group 16 element.

The group II-VI compound includes at least one selected from the group consisting of, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

The group III-V compound includes at least one selected from the group consisting of, for example, GaAs, GaP, InN, InAs, InP, and InSb.

The chalcogenide is a compound containing a VI A (16) group element, and includes, for example, CdS or CdSe. The chalcogenide may contain a mixed crystal of these elements.

The perovskite compound has a composition represented by, for example, a general formula CsPbX₃. The constituent element X includes at least one selected from the group consisting of, for example, Cl, Br, and I.

Here, the group numbers of the elements in Roman numbers are denoted by the former International Union of Pure and Applied Chemistry (IUPAC) notation or by the former Chemical Abstracts Service (CAS) notation. The group numbers of the elements in Arabic numbers are denoted by the current IUPAC notation.

A structure of a quantum dot contained in the quantum-dot layer 33 according to this embodiment will be described below in more detail with reference to a blue quantum dot QDB as an example. The blue quantum dot QDB, which is referred to as a core-shell quantum dot, has: a core; and a shell positioned at least partially around the core. In particular, as illustrated in the enlarged schematic view 102 of FIG. 1, for example, the blue quantum dot QDB includes: the core C; a first shell S1 positioned at least partially around the core C; and a second shell S2 positioned at least partially around the first shell S1.

The blue quantum dot QDB has a shell including the first shell S1 and the second shell S2. Thanks to such a feature, the blue quantum dot QDB allows the shells to protect the core C. For example, the first shell S1 and the second shell S2 may compensate for defects developed on an outer surface of the core C to protect the core C. The second shell S2 may also have a function to protect the first shell S1. Furthermore, the blue quantum dot QDB has a two-layer shell including the first shell S1 and the second shell S2. Thanks to such a feature, the blue quantum dot QDB can enhance a function that the first shell S1 and the second shell S2 has for protecting the core C. In particular, in view of further improving an advantageous effect of protecting the core C, as illustrated in the enlarged schematic view 102 of FIG. 1, the first shell S1 may cover around the core C, and the second shell S2 may cover around the first shell S1.

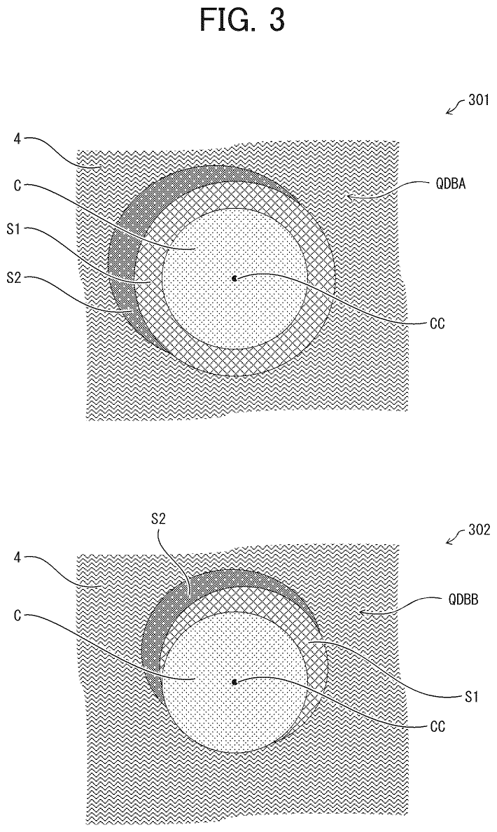

Note that the configuration of the blue quantum dot QDB according to this embodiment shall not be limited to the configuration illustrated in the enlarged schematic view 102 of FIG. 1. FIG. 3 illustrates other enlarged schematic views 301 and 302 in the vicinity of blue quantum dots in the sectional side view of the display device 1. The enlarged schematic views 301 and 302 illustrate another example of the blue quantum dots according to this embodiment.

For example, instead of the blue quantum dot QDB, the blue quantum-dot layer 33B may contain a blue quantum dot QDBA illustrated in the enlarged schematic view 301 of FIG. 3. The blue quantum dot QDBA is the same in configuration as the blue quantum dot QDB, except that the second shell S2 is formed only on a portion of an outer peripheral surface of the first shell S1.

Furthermore, instead of the blue quantum dot QDB, the blue quantum-dot layer 33B may contain a blue quantum dot QDBB illustrated in the enlarged schematic view 302 of FIG. 3. The blue quantum dot QDBB is the same in configuration as the blue quantum dot QDB, except that the second shell S2 is formed on a portion of the outer peripheral surface of the first shell S1, and that the first shell S1 is formed only on a portion of an outer peripheral surface of the core C. Here, the second shell S2 has a portion formed on the outer peripheral surface of the core C. The blue quantum dot QDBA has a portion without the second shell S2. The blue quantum dot QDBB has a portion with neither the first shell S1 nor the second shell S2. However, these portions are protected with the inorganic filler material 4 as will be described later. Hence, the quantum dots are less likely to deteriorate.

The first shell S1 contains a first shell material, and the second shell S2 contains a second shell material. Materials of the quantum dots contained in the quantum-dot layer 33, such as the first shell material and the second shell material, will be described later in detail.

Note that, in the enlarged schematic view 102 of FIG. 1, the blue quantum dot QDB is described as an example. The red quantum dot QDR and the green quantum dot QDG may also be the same in configuration as the blue quantum dot QDB except for particle diameters and materials. Specifically, each of the red quantum dot QDR and the green quantum dot QDG may also have: a core C; a first shell S1 positioned at least partially around the core C; and a second shell S2 positioned at least partially around the first shell S1.

In the quantum-dot layer 33, an average distance between the neighboring cores (i.e., an inter-core distance) may be 3 nm or more. Alternatively, the average distance between the neighboring cores may be 0.5 times as long as, or longer than, an average core diameter. The inter-core distance is an average distance between 20 neighboring cores in a space including the 20 cores. The inter-core distance may be kept longer than a distance between shells in contact with each other. The average core diameter is an average of core diameters of 20 cores when a space including the 20 cores is observed in cross-section. Each of the core diameters can be interpreted as a diameter of a circle whose area is as large as an area of the core observed in cross-section.

### Inorganic Filler Material

Furthermore, each of the red quantum-dot layer 33R, the green quantum-dot layer 33G, and the blue quantum-dot layer 33B contains the inorganic filler material 4 filling spaces between the plurality of quantum dots.

Note that, when the inorganic filler material 4 fills the spaces between the plurality of quantum dots, it means that, as illustrated in the schematic view 103 of the pair P1 in FIG. 1, the inorganic filler material 4 may fill a region K at least between the quantum dot QD1 and the quantum dot QD2. The region K is, in a cross-section of the quantum-dot layer 33, a region surrounded with: two straight lines (i.e., common outer tangent lines) in contact with outer peripheries of the quantum dot QD1 and the quantum dot QD2; and opposing outer peripheries of the quantum dot QD1 and the quantum dot QD2. Hence, as illustrated in the schematic view 104 of the pair P2 in FIG. 1, even if the quantum dot QD1 and the quantum dot QD2 are close to each other, the region K can exist and the inorganic filler material 4 fills the region K.

Furthermore, when the inorganic filler material 4 fills the spaces between the plurality of quantum dots, it does not have to mean that the entire region K between the quantum dot QD1 and the quantum dot QD2 consists only of the inorganic filler material 4. For example, the region K between the quantum dot QD1 and the quantum dot QD2 may contain such a material as an organic material different from the inorganic filler material 4. Specifically, for example, the quantum dot layer 33 may contain organic ligands that are added to increase dispersibility of the quantum dots in a solution to be used for forming a coat, and are coordinated to the outer peripheral surfaces of the quantum dots in the solution. In this case, as to the quantum-dot layer 33, for example, a weight percentage of the organic ligands to the total weight including the region K may be less than 5% in view of increasing reliability of the quantum-dot layer 33.

The inorganic filler material 4 may fill a region other than the plurality of quantum dots in the quantum-dot layer 33. For example, an outer edge (an upper surface and a lower surface) of the quantum-dot layer 33 may be covered with the inorganic filler material 4. Furthermore, the outer edge of the quantum-dot layer 33 may be formed of the inorganic filler material 4, and the quantum dots may be positioned away from the outer edge. The outer edge of the quantum-dot layer 33 does not have to be formed of the inorganic filler material 4 alone. The quantum dots may be partially exposed from the inorganic filler material 4. In the quantum-dot layer 33, the inorganic filler material 4 may be a portion except for the plurality of quantum dots.

The inorganic filler material 4 may contain the plurality of quantum dots. The inorganic filler material 4 may be formed to fill spaces formed between the plurality of quantum dots. The plurality of quantum dots may be buried at intervals in the inorganic filler material 4.

The inorganic filler material 4 may include a continuous film having an area of 1000 nm² or more in a planer direction perpendicular to the thickness direction. The continuous film may be a film whose single plane is not separated with a material other than the material forming the continuous film. The continuous film may be a seamless single film formed by chemical bonding of the inorganic filler material 4.

A concentration of the inorganic filler material 4 in the quantum-dot layer 33 is, for example, a percentage of an area that the inorganic filler material 4 occupies to the cross-section of the quantum-dot layer 33. This concentration may be 10% or more and 90% or less, and 30% or more and 70% or less, when the cross-section is observed. This concentration may be measured from, for example, a percentage of an area of an image obtained when the cross-section is observed. If the quantum dots have a core-shell structure, a concentration of the shells may be 1% or more and 50% or less. Percentages of the cores and the shells of the quantum dots and the inorganic filler material 4 may be appropriately adjusted so that the total percentage is 100% or less. If the shells and the inorganic filler material 4 cannot be distinguished from each other, the shells may be a portion of the inorganic filler material 4.

The quantum-dot layer 33 may be formed of the plurality of quantum dots and the inorganic filler material 4. When the quantum-dot layer 33 is analyzed, strength of carbon detected in a chain structure may be equal to noise or less. As seen in a known technique, if the quantum-dot layer 33 is formed of quantum dots having organic ligands, carbon chains of the organic ligands might be broken and the organic ligands per se might come off from the quantum dots as the light-emitting element is driven for a long time. In this case, the quantum dots might suffer deterioration and luminance decrease. In the present disclosure, the inorganic filler material 4 fills the quantum dots. Such a feature successfully protects the quantum dots without using organic ligands. Hence, the display device 1 according to this embodiment can achieve high reliability. In other words, the display device 1 can achieve reduction in luminance decrease observed when each of the light-emitting elements is driven for a long time.

### Concentration Gradient of Composition

In the quantum-dot layer 33 according to this embodiment, as to at least one quantum dot, at least a portion of a composition of the quantum-dot layer 33 around the core has a concentration gradient in a direction from toward a center of the core to toward around the core. In other words, as to at least one quantum dot according to this embodiment, at least a portion around the core exhibits a monotonical increase or a monotonical decrease in a concentration of at least one element from toward the center of the core to toward around the core.

Note that, in the Description, the monotonic increase and the monotonic decrease do not necessarily mean a constant increase and a constant decrease. For example, the monotonic increase and the monotonic decrease may be substantially constant in value at least in one section. In other words, as to at least one quantum dot according to this embodiment, at least a portion around the core has a substantially constant composition from toward the center of the core to toward around the core.

Furthermore, the direction from toward the center of the core to toward around the core in a quantum dot includes, but is not limited to, a direction from the center CC toward the outer peripheral surface of the core C on a line passing through the center CC of the core C, such as, for example, a direction D1 and a direction D2 illustrated in the enlarged schematic view 102 of FIG. 1. For example, the direction from toward the center of the core to toward around the core in a quantum dot may include a direction closer to a direction from the center of the core toward the outer peripheral surface of the core than to a tangent line of the outer peripheral surface of the core. Moreover, if the shape of the core is not a sphere, and thus has difficulty in defining the center, the direction from toward the center of the core to toward around the core in a quantum dot may be an outward direction substantially perpendicular to a direction along the outer periphery of the core.

In the quantum-dot layer 33 according to this embodiment, different element concentrations can be observed at least partially around the core of a quantum dot, depending on the position. Thanks to such a feature, the quantum dot layer 33 can increase design flexibility, such as bandgap, around the core of a quantum dot. In particular, a quantum dot of the quantum-dot layer 33 includes the first shell S1 and the second shell S2. Such a feature makes it possible to readily design the first shell S1 and the second shell S2 to have different bandgaps.

In the quantum-dot layer 33 according to this embodiment, a concentration gradient of the composition of the quantum-dot layer 33 is observed only at least in a portion around the core of a quantum dot. Thus, compared with a case where, for example, a plurality of materials made of different elements are included, the portion successfully reduces a difference in lattice constant depending on the position. As a result, the quantum-dot layer 33 reduces generation of dangling bonds caused by lattice constant mismatch around the core of the quantum dot, and improves efficiency in injection of the holes and the electrons into the quantum dot. Thanks to such a feature, the quantum-dot layer 33 successfully increases EQE of each of the light-emitting elements, and reduces a drive voltage of each light-emitting element so that the light-emitting element can operate on a low voltage. Whereas, the quantum-dot layer 33 according to this embodiment has the inorganic filler material 4 between the quantum dots. The inorganic filler material 4 reduces deterioration due to energization or penetration of a foreign substance, compared with an organic material containing organic ligands. Thus, the quantum-dot layer 33 increases reliability of each light-emitting element.

Hence, the light-emitting element of the display device 1 according to this embodiment, which includes the quantum dot layer 33, operates on a low voltage and improves in EQE and reliability. The display device 1 including the light-emitting element allows each of the light-emitting elements to increase in light emission efficiency and to operate on a low voltage, thereby successfully presenting an image in high luminance while saving power. Furthermore, the display device 1 improves reliability of, and increases a life of, each light-emitting element.

### Bandgap of Quantum-Dot Layer

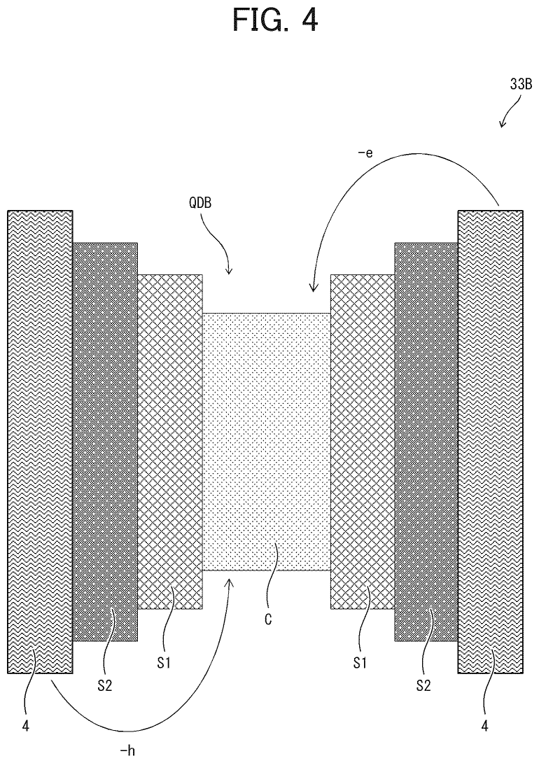

FIG. 4 is a band diagram showing an example of a bandgap of each of the portions of the blue quantum-dot layer 33B according to this embodiment. Each bandgap shown in FIG. 4 indicates bandgaps between: the core C, the first shell S1, and the second shell S2 of one of the blue quantum dots QDB; and the inorganic filler material 4 around the blue quantum dot QDB.

Note that any of the band diagrams in the Description shows the vacuum level on the upper side of the drawing. Furthermore, the right-left direction of the band diagrams in the Description represents a thickness of the display device 1 in a display direction. The left in the drawing is to the anode 31, and the right in the drawing is to the cathode 35.

For example, suppose a case where the first shell S1 and the second shell S2 cover around the core C of a blue quantum dot QDB, and the inorganic filler material 4 fills the spaces between the blue quantum dots QDB in the blue quantum-dot layer 33B. Here, as illustrated in FIG. 4, a band diagram of the blue quantum-dot layer 33B can be simplified to show that each bandgap of the first shell S1, the second shell S2, and the inorganic filler material 4 is positioned at both a right end and a left end of the bandgap of the core C.

Typically, an injection barrier of the holes to be injected from a first layer to a second layer is equivalent to a difference obtained by subtracting an ionization potential of the first layer from an ionization potential of the second layer. Furthermore, an injection barrier of the electrons to be injected from a first layer to a second layer is equivalent to a difference obtained by subtracting an electron affinity of the second layer from an electron affinity of the first layer. Furthermore, the narrower the bandgap of a material is, the smaller an ionization potential of the material tends to be and the larger the electron affinity of the material tends to be.

In the quantum-dot layer 33 according to this embodiment, at least a portion included in at least one of the quantum dots and provided around the core may have a bandgap wider toward the center of the core than toward around the core. For example, as illustrated in FIG. 4, in the blue quantum-dot layer 33B, the bandgap may be wider in the order of the first shell S1, the second shell S2, and the inorganic filler material 4. Thanks to such a feature, around the core C of the blue quantum dot QDB, the bandgap toward around the core C is gradually wider than the bandgap toward the center of the core C.

Thanks to such a feature, the quantum-dot layer 33 can reduce the injection barriers against the holes and the electrons to be injected from toward around the core into the core, thereby successfully increasing efficiency in injecting the holes and the electrons into the core. Furthermore, the quantum-dot layer 33 can raise the injection barriers against the holes and the electrons to be injected from the core to each of the shells, or from each of the shells to the inorganic filler material 4. Hence, the quantum-dot layer 33 successfully keeps the holes and the electrons, injected into the core, from flowing out of the core without recombination.

Hence, the quantum-dot layer 33 according to this embodiment increases a concentration of the holes and the electrons in the core, and increases efficiency in recombination of the holes and the electrons, thereby improving light emission efficiency in each of the light-emitting elements.

The above configuration may be achieved with a concentration gradient provided to the composition around the core so that, around the core, the bandgap gradually narrows from around the core toward the center of the core.

### Compositions of Shell and Inorganic Filler Material

The structure described above can be achieved, for example, by suitably designing a composition of either the materials of the shells around the core or the material of the inorganic filler material 4. For example, x, y, and z are real numbers satisfying 0≤x<y<z≤1, and A, B, and C are elements that are different from one another. In this case, the first shell S1 of a blue quantum dot QDB may contain AₓB₁₋ₓC as the first shell material, and the second shell S2 of the blue quantum dot QDB may contain A_{y}B_{1-y}C as the second shell material. Furthermore, the inorganic filler material may contain A_{z}B_{1-z}C.

Here, around the core C of the blue quantum dot QDB, the element A monotonously increases in concentration, and the element B monotonously decreases in concentration, from the first shell S1 toward the inorganic filler material 4. As can be seen, in the quantum-dot layer 33, at least a portion of the composition of the quantum-dot layer 33 around the core of a quantum dot can be provided with a concentration gradient in a direction from toward the center of the core to toward around the core, using a simple configuration.

Described below with reference to a table will be exemplary materials of the quantum-dot layer 33 satisfying the above formulas.

TABLE 1

| | First | Second | Inorganic | | | |
|---|---|---|---|---|---|---|
| | Shell | Shell | Filler | | | |
| Core | Material | Material | Material | A | B | C |
| InP | ZnS (x = 0) | Zn_{1-y}Mg_{y}S | Zn_{1-y}Mg_{z}S | Mg | Zn | S |
| ZnSe | ZnS (x = 0) | Zn_{1-y}Mg_{y}S | Zn_{1-y}Mg_{z}S | Mg | Zr | S |
| ZnSeTe | ZnS (x = 0) | Zn_{1-y}Mg_{y}S | Zn_{1-y}Mg_{z}S | Mg | Zn | S |
| CdSe | ZnS (x = 0) | Zn_{1-y}Mg_{y}S | Zn_{1-y}Mg_{z}S | Mg | Zn | S |
| InP | ZnSe (x = 0) | ZnSe_{1-y}S_{y} | ZnS (z = 1) | S | Se | Zn |
| ZnSe | ZnSe₁₋ₓSₓ | ZnSe_{1-y}S_{y} | ZnS (z = 1) | S | Se | Zn |
| ZnSeTe | ZnSe (x = 0) | ZnSe_{1-y}S_{y} | ZnS (z = 1) | S | Se | Zn |
| AgGaSeS | ZnSe (x = 0) | ZnSe_{1-y}S_{y} | ZnS (z = 1) | S | Se | Zn |
| CdSe | ZnSe (x = 0) | ZnSe_{1-y}S_{y} | ZnS (z = 1) | S | Se | Zn |
| CdSe | CdS (x = 0) | Cd_{1-y}Zn_{y}S | ZnS (z = 1) | Zn | Cd | S |
| AgGaSeS | GaSe (x = 0) | CaSe_{1-y}S_{y} | GaS (z = 1) | S | Se | Ga |
| InP | ZnSe (x = 0) | ZnSe_{1-y}S_{y} | ZnSe_{1-z}S_{z} | S | Se | Zn |
| ZnSe | ZnSe₁₋ₓSₓ | ZnSe_{1-y}S_{y} | ZnSe_{1-z}S_{z} | S | Se | Zn |
| ZnSeTe | ZnSe (x = 0) | ZnSe_{1-y}S_{y} | ZnSe_{1-z}S_{z} | S | Se | Zn |
| AgGaSeS | ZnSe (x = 0) | ZnSe_{1-y}S_{y} | ZnSe_{1-z}S_{z} | S | Se | Zn |
| CdSe | ZnSe (x = 0) | ZnSe_{1-y}S_{y} | ZnSe_{1-z}S_{z} | S | Se | Zn |
| AgGaSeS | GaSe (x = 0) | CaSe_{1-y}S_{y} | GaSe_{1-z}S_{z} | S | Se | Ga |

In the above table, the column “Core” shows examples of a material that can be used for the core C of a quantum dot of the quantum-dot layer 33. The columns “First Shell Material”, “Second Shell Material”, and “Inorganic Filler Material” show materials that can be used when the core of the quantum dot of the quantum-dot layer 33 includes a material shown in the column “Core”. The materials satisfy the above formulas. The columns “A”, “B”, and “C” show elements corresponding to A, B, and C of the above formulas in a case where the quantum-dot layer 33 includes materials shown in the column “First Shell Material”, “Second Shell Material”, and “Inorganic Filler Material”. The materials in the columns “First Shell Material”, “Second Shell Material”, and “Inorganic Filler Material” are in stoichiometry in which a composition of the actual compound is the same as the chemical formula. However, the material in the column “Core” does not have to be in stoichiometry.

Note that, in the column “First Shell Material” in the above table, x=0 means that the value of x in the above formulas is 0; in other words, the material does not contain the element A. Furthermore, in the column “Inorganic Filler Material”, z=1 means that the value of z in the above formulas is 1; in other words, the material does not contain the element B.

Studied here is how the bandgap of each of the portions of the quantum-dot layer 33 is designed to improve efficiency in injecting the holes and the electrons into the quantum dots of the quantum-dot layer 33.

A magnitude of a current flowing through a semiconductor having a bandgap E_{g} is proportional to an intrinsic carrier density of the semiconductor; in other words, the magnitude of the current is proportional to exp (−E_{g}/kT). Wherein k is a Boltzmann constant, and T is a temperature of the semiconductor.

Hence, ΔE_{g} is a difference in bandgap either between the inorganic filler material 4 and the second shell S2, or between the second shell S2 and the first shell S1. In this case, in view of improving efficiency in injecting the holes and the electrons into the core C, a relationship of exp (ΔE_{g}/kT)>2 may hold; in other words, a relationship of ΔE_{g}>0.036 eV may hold.

For example, suppose the first shell material, the second shell material, and the inorganic filler material 4 contain ZnSe₁₋ₓSₓ (0≤x≤1). Here, if a relationship of x=0 holds, a bandgap of ZnSe₁₋ₓSₓ, namely, ZnSe, is 2.7 eV. If a relationship of x=1 holds, a bandgap of ZnSe₁₋ₓSₓ, namely, ZnS, is 3.6 eV. Thus, the bandgap of ZnSe₁₋ₓSₓ increases by 0.9 eV as x increases from 0 to 1.

Assuming that the bandgap of ZnSe₁₋ₓSₓ increases linearly with an increase of x, the bandgap of ZnSe₁₋ₓSₓ increases by 0.036 eV as x increases by 0.04. Thus, in order to satisfy ΔE_{g}>0.036 eV, x may be raised in increments of 0.04 in the order of the first shell material, the second shell material, and the inorganic filler material 4 between the inorganic filler material 4 and the second shell S2 and between the second shell S2 and the first shell S1. Hence, in the above case, in view of improving efficiency in injecting the holes and the electrons into the core C, a relationship of y−x>0.04 and z−y>0.04 may hold.

Furthermore, in view of reducing the lattice constant mismatch among the first shell material, the second shell material, and the inorganic filler material 4 around the core C, a difference between the value x and the value y and a difference between the value y and the value z may take the same value or may take a value close the same value. In other words, in view of the above viewpoint, the value y may be either an intermediate value between the value x and the value z, or a value close to the intermediate value. For example, a relationship of 0.7x+0.3z<y<0.3x+0.7z may hold.

The inorganic filler material 4 may contain magnesium zinc sulfide (MgZnS). Magnesium zinc sulfide has a relatively wide bandgap. Hence, the inorganic filler material 4 containing zinc magnesium sulfide can reduce leakage of a current flowing between the anode 31 and the cathode 35 not through the quantum dots of the quantum-dot layer 33.

The inorganic filler material 4 may contain zinc selenium sulfide (ZnSeS). Zinc selenium sulfide has a relatively narrow bandgap. Hence, the inorganic filler material 4 containing zinc selenium sulfide increases efficiency in injecting the holes and the electrons into the quantum dots of the quantum-dot layer 33.

In view of sufficiently obtaining an advantageous effect of the first shell S1 and the second shell S2 protecting the core C, each of a thickness T1 of the first shell S1 and a thickness T2 of the second shell S2 may be 0.5 nm or more. Furthermore, in view of reducing a decrease in efficiency in injecting the holes and the electrons into the core C using the first shell S1 and the second shell S2, each of the thickness T1 and the thickness T2 may be 2.5 nm or less.

Note that the thickness T1 and the thickness T2 may be respectively one time or more and five times or less than a lattice constant of the first shell S1 and a lattice constant of the second shell S2. Moreover, the thickness T1 and the thickness T2 may be either the same as, or different from, each other. In addition, the thickness T1 and the thickness T2 may be either substantially uniform, or different depending on the position, around the core C.

Note that the first shell material, the second shell material, and the inorganic filler material 4 may have, but not limited to, a substantially constant composition. For example, each of the first shell material, the second shell material, and the inorganic filler material 4 may have a concentration gradient of the composition in a direction from toward the center of the core C to toward around the core C. In other words, in each of the first shell material, the second shell material, and the inorganic filler material 4, a concentration of any given element may gradually increase or gradually decrease in the direction from toward the center of the core C to toward around the core C.

In particular, in this embodiment, at least a portion of the composition of the inorganic filler material 4 of the quantum-dot layer 33 may have, at least partially around at least one core C, a concentration gradient in the direction from toward the center of the core C to toward around the core C. Such a feature can be achieved when, for example, the core, the first shell S1, and the second shell S2 are formed to be able to further reduce dangling bonds at the boundary surfaces, and when the bandgaps are designed by designing the concentration gradient of the composition of the inorganic filler material 4. Hence, thanks to the above feature, the quantum-dot layer 33 can reduce density of dangling bonds around a core of a quantum dot contained in the quantum-dot layer 33, and increase design flexibility around the core.

The structure of the inorganic filler material 4 may as well be seen to be the above one when the cross-section of the quantum-dot layer 33 is observed in a width of approximately 100 nm. The structure does not have to be observed throughout the quantum-dot layer 33. The inorganic filler material 4 may contain a substance different from the main material; that is, for example, an inorganic substance such as an inorganic semiconductor. The substance may be contained as, for example, an additive.

The structures of the first shell S1 and the second shell S2 may be checked by observation of a sample of the quantum-dot layer 33 using, for example, energy-dispersive X-ray spectrometry with a transmission electron microscope (TEM-EDX). The sample may be obtained by, for example, focused ion beam (FIB) processing on the quantum-dot layer 33. The technique makes it possible to analyze the composition of the quantum-dot layer 33 with a spatial resolution of approximately 1 nm. For example, the composition of the quantum-dot layer 33 may be analyzed by observing signal intensity of either the element A or the element B with respect to signal intensity of the element C obtained by the TEM-EDX.

### Remarks on Light-Emitting Element Layer

Note that the configuration of the light-emitting-element layer 3 shall not be limited to the configuration illustrated in the schematic sectional side view 101 of FIG. 1. For example, the light-emitting-element layer 3 may further include a capping layer above the cathode 35, in order to improve efficiency in releasing light from each of the light-emitting elements. Furthermore, the light-emitting element layer 3 may include a hole injection layer between each of the anodes 31 and the hole transport layer 32.

In this embodiment, each light-emitting element may release light of the quantum-dot layer 33 from toward either the anode 31 or the cathode 35 whichever is a light-transparent electrode. In this case, either the anode 31 or the cathode 35 whichever is an electrode across from the light-transparent electrode may be reflective to light, in order to increase efficiency in releasing light from the quantum-dot layer 33.

In particular, in this embodiment, if each light-emitting element releases light of the quantum-dot layer 33 from toward either the anode 31 or the cathode 35 whichever is an electrode formed toward the substrate 2; that is, if each light-emitting element releases light from toward the anode 31 in this embodiment, the substrate 2 may be transparent to light.

In this embodiment, of the anode 31 and the cathode 35, the light-emitting-element layer 3 has the anode 31 provided toward the substrate 2. However, this embodiment shall not be limited to such a case. For example, the light-emitting-element layer 3 may have the cathode 35, the electron transport layer 34, the quantum-dot layer 33, the hole transport layer 32, and the anode 31 in the stated order above the substrate 2. In this case, the cathode 35 may be formed into an island shape for each of the subpixels, and each cathode 35 may be electrically connected to a pixel circuit of the substrate 2. Furthermore, the anode 31 may be formed in common to the plurality of subpixels.

### Method for Producing Display Device: Until Formation of Hole Transport Layer

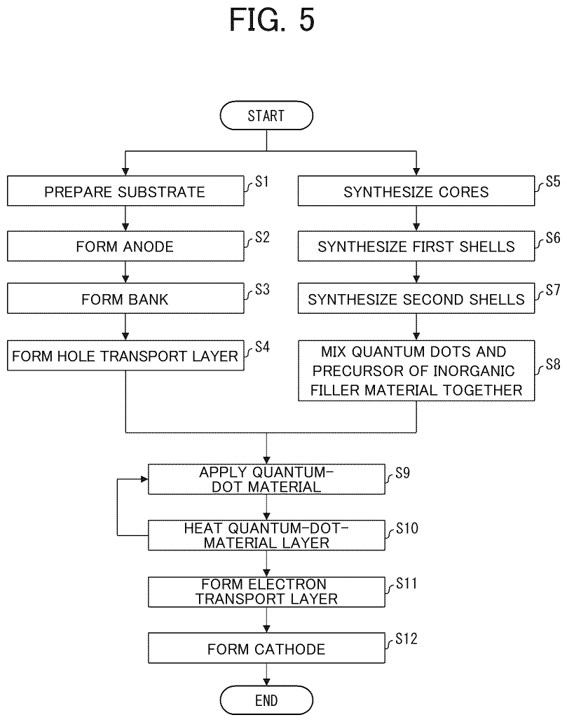

Described below is a method for producing the display device 1 according to this embodiment, with reference to FIG. 5. FIG. 5 is a flowchart showing the method for producing the display device 1 according to this embodiment.

With reference to FIG. 5, in the method for producing the display device according to this embodiment, first, the substrate 2 is prepared (Step S1). In this embodiment, for example, a thin-film transistor may be formed on such a substrate as a glass substrate or a film substrate for each of the subpixels so that the substrate 2 may be produced to include a pixel circuit for each subpixel. Furthermore, for example, a driver is formed in a peripheral edge portion of the substrate 2 so that the picture-frame unit NA may be formed.

Next, the anode 31 is formed on the substrate 2 (Step S2). In forming the anode 31, for example, a thin film of such a material as a metal material may be deposited on the substrate 2 by such a technique as sputtering. After that, the thin film may be patterned by such a technique as dry-etching to form the anode 31.

Next, the bank BK is formed on the substrate 2 and the anode 31 (Step S3). In forming the bank BK, for example, a photosensitive resin material may be applied to the substrate 2 and the anode 31 to form a coat. After that, the coat may be patterned by such a technique as photolithography to form the bank BK.

Next, the hole transport layer 32 is formed on the anode 31 and the bank BK (Step S4). In forming the hole transport layer 32, for example, a hole-transporting material may be applied to the anode 31 and the bank BK to form the hole transport layer 32.

### Method for Producing Display Device: Synthesis of Quantum Dot Material

In the method for producing the display device 1 according to this embodiment, a step is carried out between Step S1 and Step S4 to synthesize a solution serving as a material of the quantum-dot layer 33. In synthesizing the solution, for example, quantum dots are synthesized first.

At the step of synthesizing the quantum dots, cores C are synthesized first (Step S5). The cores C may be synthesized by a known technique such as growing crystals in a solvent.

Next, a first shell synthesizing step is carried out to synthesize the first shells S1 (Step S6). In synthesizing the first shells S1, a material containing, in the composition, an element to be contained in the first shells S1 may be added to a solution in which the cores C are dispersed, so that the first shells S1 grow on a surface of each of the cores C.

For example, the material to be added to the solution at Step S6 may include a zinc source containing such a substance as zinc carboxylate, a magnesium source containing such a substance as magnesium carboxylate, a selenium source containing such a substance as phosphine selenide, or a sulfur source containing such a substance as phosphine sulfide. At Step S6, a thickness or a forming position of the first shells S1 may be controlled by such factors as concentration of the additive material in relation to the solution and a time period for the first shells S1 to grow.

Next, a second shell synthesizing step is carried out to synthesize the second shells S2 (Step S7). In synthesizing the second shells S2, a material containing, in the composition, an element to be contained in the second shells S2 may be added to the solution in which the cores C provided with the first shells S1 are dispersed, so that the second shells S2 grow on a surface of either the first shells S1 or the cores C.

The material to be added to the solution at Step S7 may be the same as the material added to the solution at Step S6, except for a ratio of the concentrations of the materials. The material to be added to the solution at Step S7 may be lower in concentration of the selenium source, and higher in concentration of the sulfur source, than, for example, the material to be added to the solution at Step S6. Thanks to such a feature, a concentration gradient of the composition can be provided by a simple technique between a first shell S1 and a second shell S2.

Note that the method for synthesizing the shells around the cores C shall not limited to the above method. For example, a first material may be added to the solution in which the cores C are dispersed. After that, the shells may be made grow around the cores C, and a second material may be delivered in the form of droplets little by little into the solution. For example, the zinc source and the selenium source may be added to the solution in which the cores C are dispersed. After that, the sulfur source may be delivered in the form of droplets. Hence, each of the shells formed around a core C may have a concentration gradient of the composition from toward the center CC of the core C to toward around the core C.

As can be seen, the quantum dots each containing the core C, the first shell S1, and the second shell S2 are synthesized in the solution. Note that, in order to ensure the dispersibility of the quantum dots in the solution, such substances as organic ligands may be added to the solution between Step S5 and Step S7.

After Step S7, for example, a precursor of the inorganic filler material 4 is added to the solution in which the quantum dots are dispersed. The quantum dots and the precursor of the inorganic filler material 4 are mixed together (Step S8). The precursor to be added to the solution to form the inorganic filler material 4 is a material containing, in the composition, an element contained in the inorganic filler material 4 to be formed at a downstream step. In particular, at Step S8, a concentration of each of the elements of the precursor may be designed so that a concentration gradient of the composition is formed across the first shell S1, the second shell S2, and the inorganic filler material 4 in the quantum-dot layer 33 formed at a downstream step.

At Step S8, the precursor of the inorganic filler material 4 may be added to the solution containing the quantum dots in a manner that a mixture solution of the precursor and a solvent such as N, N-dimethylformamide (DMF) is added to the solution containing the quantum dots. The precursor may include, for example, a zinc source containing such a substance as zinc carboxylate, a magnesium source containing such a substance as magnesium carboxylate, a selenium source containing such a substance as selenourea, or a sulfur source containing such a substance as phosphine sulfide.

In particular, at Step S6, the ratio of the materials containing the elements may be adjusted so that AₓB₁₋ₓC described above is contained in the first shell material to form the first shell S1. Moreover, at Step S7, the ratio of the materials containing the elements may be adjusted so that A_{y}B_{1-y}C described above is contained in the second shell material to form the second shell S2. Furthermore, at Step S8, the ratio of the elements in the precursor may be adjusted so that A_{z}B_{1-z}C described above is contained to form the inorganic filler material 4 at a downstream step. Such features make it possible to readily form the quantum-dot layer 33 so that at least a portion of a composition of the quantum-dot layer 33 around at least one core C has a concentration gradient in a direction from toward the center of the core C to toward around the core C only by adjusting the ratio of the elements of the materials at each of the steps.

Note that if the display device 1 includes subpixels in a plurality of emission colors, Steps S5 to S8 may be repeated for each of the emission colors, in order to synthesize a mixture solution of the quantum dots corresponding to each of the emission colors and the precursor of the inorganic filler material 4.

### Method for Producing Display Device: Formation of Quantum-Dot Layer

After Step S4 and Step S8 are completed, a step is carried out to form the quantum-dot layer 33. At the step of forming the quantum-dot layer 33, for example, first, a quantum-dot material is applied to the hole transport layer 32 formed for a subpixel corresponding to any given color (Step S9). For example, applied to the hole transport layer 32 formed for a blue subpixel is a mixture solution of blue quantum dots QDB and the precursor of the inorganic filler material 4. The solution is applied as a quantum dot material. In applying the quantum dot material, for example, an ink-jet printing nozzle may be used to discharge the quantum dot material at a position between banks BK and on the hole transport layer 32 overlapping with a subpixel in any given emission color, in a plan view of the display device 1. Thus, formed on the hole transport layer 32 corresponding to a subpixel in a certain emission color is a quantum-dot-material layer containing quantum dots in the corresponding emission color and the precursor of the inorganic filler material 4.

Next, the quantum-dot-material layer is heated (Step S10). At Step S10, for example, each of the layers including the quantum-dot-material layer and provided above the substrate 2 is heated for 30 minutes in an atmosphere at 250° C. Thus, the precursor in the quantum-dot-material layer is modified, and the inorganic filler material 4 is formed. Here, the precursor in the quantum-dot-material layer is modified by the heat added at Step S10, and the inorganic filler material 4 is successively formed around the quantum dots in the quantum-dot-material layer. Hence, at Step S10, the inorganic filler material 4 is formed to fill the spaces between the plurality of quantum dots. As can be seen, the quantum-dot layer is formed to contain the plurality of quantum dots and the inorganic filler material 4 filling the spaces between the quantum dots. Note that, if the solution contains organic ligands, the heat given at Step S10 vaporizes the organic ligands in the solution so that a weight percentage of the organic ligands in the light-emitting layer may be less than 5%.

Note that Step S9 and Step S10 are repeatedly carried out for each emission color, with changes made to the emission colors and the discharge positions of the quantum dots in the solution discharged at Step S9. Hence, the quantum-dot layer 33 is formed to include the red quantum-dot layer 33R, the green quantum-dot layer 33G, and the blue-quantum-dot layer 33B.

Note that when Step S9 and Step S10 are repeatedly carried out, a quantum-dot layer of any given subpixel that has already been formed is heated at Step S10. However, because the spaces between the quantum dots in the quantum-dot layer are filled with the inorganic filler material 4, the quantum dots are protected from the heat by the inorganic filler material 4. Hence, the method for producing the display device 1 described above can reduce deterioration of the quantum dots in the quantum dot layer.

Furthermore, at Step S9 and Step S10, the inorganic filler material 4 has, but not limited to, a substantially uniform composition. For example, at Step S10, the quantum-dot-material layer may be heated while a material containing any given element is delivered in the form of droplets to the quantum-dot-material layer. Thus, a gradual change may be made to the composition of the inorganic filler material 4 that grows from the outer peripheral surface of the quantum dots in the quantum-dot-material layer. As can be seen, at Step S10, the inorganic filler material 4 may be formed so that at least a portion of a composition of the inorganic filler material 4 may have a concentration gradient in a direction from toward the center CC of the core C of at least one quantum dot to toward around the core C.

Furthermore, this embodiment describes an example in which Step S9 and Step S10 are repeatedly carried out multiple times. However, this embodiment shall not be limited to such an example. For example, at Step S9 of this embodiment, application of the quantum dot materials may be completed for the plurality of emission colors. Then, Step S10 may be carried out to heat the quantum-dot-material layers at once for the plurality of emission colors.

Moreover, if the inorganic filler material 4 has a concentration gradient, the cores C may be provided with shells having a uniform composition. In this case, as well, the quantum-dot layer can be formed so that at least a portion of the composition of the quantum-dot layer around the core C of at least one quantum dot may have a concentration gradient in the direction from toward the center CC of the core C to toward around the core C.

As a method for forming the quantum-dot layer 33 for each of the subpixels, this embodiment describes a method for applying a quantum dot material for each of the subpixels, using such an application technique as inkjet printing. However, a method for forming the quantum-dot layer 33 shall not be limited to such a method. The quantum-dot layer 33 may be produced by patterning using, for example, a lift-off technique.

For example, a layer of photosensitive resin is formed by such a technique as photolithography to have an opening only in a position corresponding to a certain subpixel. After the layer is formed, a quantum dot material is formed in common over a plurality of subpixels. After that, an appropriate developing solution is used to remove the layer of photosensitive resin. Hence, the quantum-dot-material layer can be formed only in the position corresponding to the certain subpixel. After that, the quantum-dot-material layer may be heated to form the quantum-dot layer only for the certain subpixel.

In this case, when the photosensitive resin layer is removed, a quantum-dot layer of any given subpixel that has already been formed is exposed to the developing solution. Hence, in the above method, the quantum-dot-material layer may be heated every time the quantum-dot-material layer is patterned, and the quantum-dot layer may be formed one by one. In this case, the spaces between the quantum dots in the quantum-dot layer are filled with the inorganic filler material 4. Hence, the quantum dots, which are included in the already-formed quantum-dot layer, are protected from the developing solution by the inorganic filler material 4. Hence, the above method as well can reduce deterioration of the quantum dots in the quantum dot layer.

### Method for Producing Display Device: From Formation of Electron Transport Layer and Thereafter, and Summary

After the formation of the quantum-dot layer 33, the electron transport layer 34 is formed on the quantum-dot layer 33 (Step S11). In forming the electron transport layer 34, for example, an electron-transporting material may be applied to the quantum-dot layer 33 to form the electron transport layer 34.

Next, the cathode 35 is formed on the electron transport layer 34 and the bank BK (Step S12). The cathode 35 may be, for example, a thin film formed of such a material as metal material. The metal material may be deposited by, for example, sputtering over the electron transport layer 34 and the bank BK, in order to form the cathode 35. Note that an upper layer of the cathode 35 may be provided with a not-shown sealing layer to keep the light-emitting element from foreign substances including water, oxygen, and organic substances such as dust generated during the production steps. Furthermore, above the sealing layer, such components as a functional film, a touch panel, and a polarizing plate film may be formed to have, as necessary, at least one of, for example, an adaptive optics correction function, a touch sensor function, and a protection function. This is how the light-emitting-element layer 3 exemplified in the schematic sectional side view 101 of FIG. 1 is formed on the substrate 2, and a process of producing the display device 1 is completed.

The process of producing the display device 1 according to this embodiment includes a first step of forming, at Step S6 or Step S7, a shell in which at least a portion of a composition of the shell has a concentration gradient in a direction from toward the center of the core C to toward around the core C. Alternatively, the producing process includes a second step of forming, at Step S10, the quantum-dot layer 33 in which at least a portion of a composition of the inorganic filler material 4 has a concentration gradient in a direction from toward the center of at least one core C toward around the core C.

In particular, the method for producing the display device 1 according to this embodiment includes at least one of the first step or the second step. Hence, the method for producing the display device 1 according to this embodiment can produce the display device 1 including a light-emitting element having the quantum-dot layer 33 so that at least a portion of a composition of the quantum-dot layer 33 around at least one core C has a concentration gradient in a direction from toward a center of the core C to toward around the core C.

### Second Embodiment

### Two Quantum-Dot Layers

Another embodiment of present disclosure will be described below. Note that, for convenience in description, like reference signs designate members having identical functions between this embodiment and the above embodiment. These members will not be elaborated upon repeatedly.

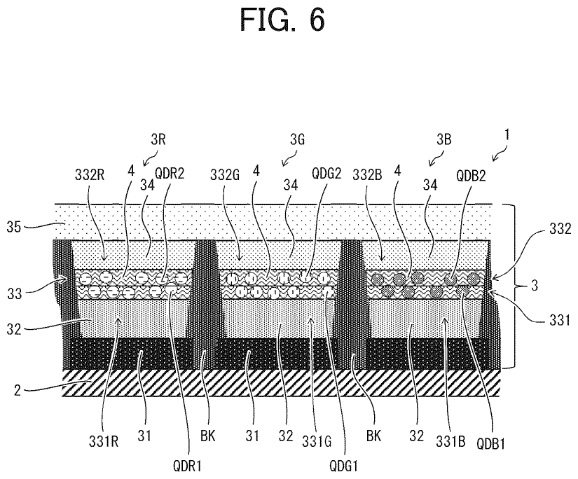

FIG. 6 illustrates a schematic sectional side view of the display device 1 according to this embodiment. The display device 1 according to this embodiment may be the same in configuration as the display device 1 according to the previous embodiment, except for the quantum-dot layer 33. The quantum-dot layer 33 according to this embodiment includes: a first quantum-dot layer 331; and a second quantum-dot layer 332 provided toward the cathode 35 with respect to the first quantum-dot layer.

In this embodiment, the first quantum-dot layer 331 and the quantum-dot layer 332 respectively include a first red quantum-dot layer 331R and a second red quantum-dot layer 332R in a position corresponding to a red subpixel. Furthermore, the first quantum-dot layer 331 and the second quantum-dot layer 332 respectively include a first green quantum-dot layer 331G and a second green quantum-dot layer 332G in a position corresponding to a green subpixel. Moreover, the first quantum-dot layer 331 and the quantum-dot layer 332 respectively include a first blue quantum-dot layer 331B and a second blue quantum-dot layer 332B in a position corresponding to a blue subpixel.

In other words, in this embodiment, the red quantum-dot layer 33R includes: the first red quantum-dot layer 331R; and the second red quantum-dot layer 332R provided toward the cathode 35 with respect to the first red quantum-dot layer 331R. Furthermore, the green quantum-dot layer 33G includes: the first green quantum-dot layer 331G; and the second green quantum-dot layer 332G provided toward the cathode 35 with respect to the first green quantum-dot layer 331G. Furthermore, the blue quantum-dot layer 33B includes: the first blue quantum-dot layer 331B; and the second blue quantum-dot layer 332B provided toward the cathode 35 with respect to the first blue quantum-dot layer 331B.

### Thickness of Shell of Quantum Dot

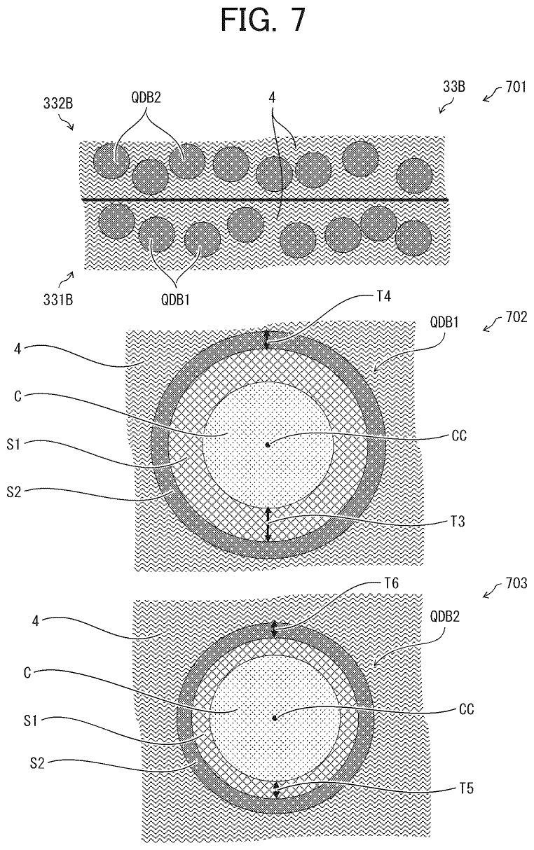

The first quantum-dot layer 331 and the second quantum-dot layer 332 will be described below in detail with reference to FIG. 7. FIG. 7 illustrates: an enlarged schematic view 701 of the blue quantum-dot layer 33B in the sectional side view of the display device 1 in FIG. 6; and an enlarged schematic view 702 and an enlarged schematic view 703 in the vicinities of a first blue quantum dot QDB1 and a second blue quantum dot QDB2 in the sectional side view of the display device 1 in FIG. 6.

As illustrated in the enlarged schematic view 701 of FIG. 7, the blue quantum-dot layer 33B according to this embodiment contains: a plurality of the first blue quantum dots QDB1 in the first blue quantum-dot layer 331B; and a plurality of the second blue quantum dots QDB2 in the second blue quantum-dot layer 332B. Furthermore, the blue quantum-dot layer 33B according to this embodiment contains, in both the first blue quantum-dot layer 331B and the second blue quantum-dot layer 332B, the inorganic filler material 4 filling spaces between the plurality of first blue quantum dots QDB1 and spaces between the plurality of second blue quantum dots QDB2.

As illustrated in the enlarged schematic view 702 of FIG. 7, each of the first blue quantum dots QDB1 includes: the first shell S1 having a thickness of T3; and the second shell S2 having a thickness of T4. Furthermore, as illustrated in the enlarged schematic view 703 of FIG. 7, each of the second blue quantum dots QDB2 includes: the first shell S1 having a thickness of T5; and the second shell S2 having a thickness of T6. Otherwise, the first blue quantum dot QDB1 and the second blue quantum dot QDB2 are the same in configuration as the blue quantum dot QDB.

In this embodiment, the thickness T3 is thicker than the thickness T5. Furthermore, a sum of the thickness T3 and the thickness T4 is greater than a sum of the thickness T5 and the thickness T6. Note that the thickness T4 may be thinner than the thickness T5.

Hence, the shell of the first blue quantum dot QDB1 is thicker than the shell of the second blue quantum dot QDB2. Note that the shell of the first blue quantum dot QDB1 illustrated in the enlarged schematic view 702 of FIG. 7 is thicker than the shell of the second blue quantum dot QDB2 in any given position. However, a thickness of the shell of the first blue quantum dot QDB1 shall not be limited to such a thickness. For example, the shell of the first blue quantum dot QDB1 may be at least partially thicker than the shell of the second blue quantum dot QDB2.

Note that, in this embodiment, the number of quantum dots per unit volume contained in the quantum dot layer 33 is substantially the same as the number of quantum dots per unit volume contained in the quantum dot layer 33 according to the previous embodiment. Whereas, the shell of the first blue quantum dot QDB1 in the first blue quantum-dot layer 331B is thicker than the shell of the second blue quantum dot QDB2 in the second blue quantum-dot layer 332B.

Hence, a volume rate of the first blue quantum dots QDB1 in the first blue quantum-dot layer 331B is greater than a volume rate of the second blue quantum dots QDB2 in the second blue quantum-dot layer 332B. Hence, an average distance between outer peripheral surfaces of two first blue quantum dots QDB1 in the first blue quantum-dot layer 331B is shorter than an average distance between outer peripheral surfaces of two second blue quantum dots QDB2 in the second blue quantum-dot layer 332B. Hence, an effective thickness of the inorganic filler material 4 in the first blue quantum-dot layer 331B is thinner than an effective thickness of the inorganic filler material 4 in the second blue quantum-dot layer 332B.

As described in this embodiment, when a plurality of quantum dots having shells with different thicknesses are stacked on top of another, if the quantum-dot layer 33 contains not the inorganic filler material 4 but organic ligands, a surface of the quantum-dot layer might have large asperities. In this embodiment, the quantum-dot layer 33 is filled with the inorganic filler material 4. Hence, the asperities of the surface of the light-emitting layer can be maintained small. Hence, the display device 1 according to this embodiment allows a current to be injected uniformly into the quantum-dot layer 33 of each of the light-emitting elements. Such a feature can reduce a difference in degree of luminance reduction depending on a position of the quantum-dot layer 33 when the display device 1 is driven for a long time, and the display device 1 can achieve high reliability.

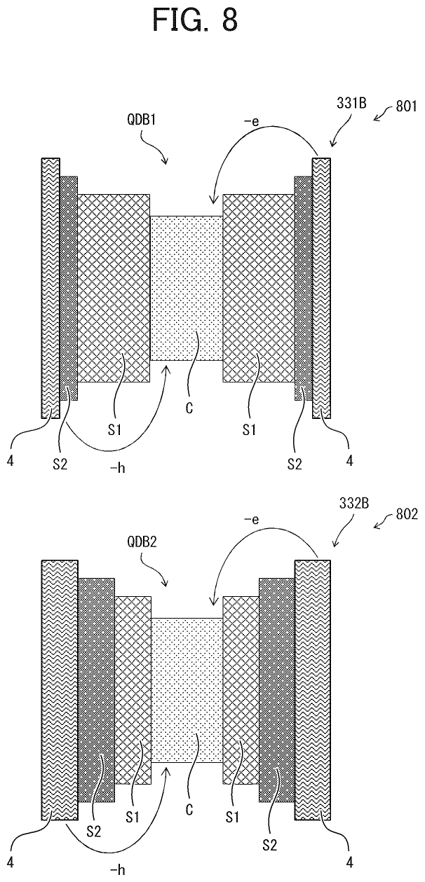

FIG. 8 illustrates band diagrams each showing an exemplary bandgap of each of the portions of the blue quantum-dot layer 33B according to this embodiment. A band diagram 801 of FIG. 8 indicates bandgaps between: the core C, the first shell S1, and the second shell S2 of one of the first blue quantum-dots QDB1; and the inorganic filler material 4 around each of the quantum dots. A band diagram 802 of FIG. 8 indicates bandgaps between: the core C, the first shell S1, and the second shell S2 of one of the second blue quantum-dots QDB2; and the inorganic filler material 4 around each of the quantum dots.

Note that the inorganic filler material 4 around the first blue quantum dot QDB1 in the band diagram 801 is thinner than the inorganic filler material 4 around the second blue quantum dot QDB2 in the band diagram 802. This shows that, as described above, the effective thickness of the inorganic filler material 4 in the first blue quantum-dot layer 331B is thinner than the effective thickness of the inorganic filler material 4 in the second blue quantum-dot layer 332B.

FIGS. 7 and 8 show the blue quantum-dot layer 33B as an example. The red quantum-dot layer 33R and the green quantum-dot layer 33G may also be the same in configuration as the blue quantum-dot layer 33B except for particle diameters and materials of the contained quantum dots. In other words, the shell of the first red quantum dot QDR1 included in the first red quantum-dot layer 331R is at least partially thicker than the shell of the second red quantum dot QDR2 included in the second red quantum-dot layer 332R. Furthermore, the shell of the first green quantum dot QDG1 included in the first green quantum-dot layer 331G is at least partially thicker than the shell of the second green quantum dot QDG2 included in the second green quantum-dot layer 332G.

### Reduction in Electron Excess Due to Difference in Shell Thicknesses

In this embodiment, the quantum dots contained in the first quantum dot layer 331 are greater in thickness of shells than the quantum dots contained in the second quantum dot layer 332. Accordingly, the inorganic filler material 4 contained in the quantum-dot layer 331 is thinner than the inorganic filler material 4 contained in the quantum-dot layer 332. Hence, efficiency in injecting carriers from each of the charge transport layers into the quantum dots contained in the first quantum-dot layer 331 is higher than efficiency in injecting carriers from each of the charge transport layers into the quantum dots contained in the second quantum-dot layer 332.

Furthermore, the first quantum-dot layer 331 is positioned toward the anode 31 with respect to the second quantum-dot layer. Hence, efficiency in injecting the holes into the quantum dots contained in the first quantum-dot layer 331 is particularly higher than efficiency in injecting the holes into the quantum dots contained in the second quantum-dot layer 332. Hence, as the whole quantum-dot layer 33, the efficiency in injecting the holes into the quantum dots increases with respect to the efficiency in injecting the electrons into the quantum dots.

Typically, as to an electroluminescence light-emitting element containing quantum dots as a light-emitting material, such a factor as high mobility of the electrons with respect to the holes could cause electron excess; that is, the concentration of the electrons to be injected into the quantum-dot layer is higher than the concentration of the holes. Because of the electron excess in the quantum-dot layer, the quantum-dot layer might exhibit an increase in deactivation processes including generation of Auger electrons because of, for example, transfer of energy between the electrons. Thus, the electron excess might cause, for example, a decrease in light emission efficiency of the light-emitting element, or a progress in deactivation of quantum dots included in the light-emitting element.

As described above, the quantum-dot layer 33 according to this embodiment increases the efficiency in injecting the holes into each of the quantum dots with respect to the efficiency in injecting the electrons into each of the quantum dots. Hence, each of the light-emitting elements of the display device 1 according to this embodiment reduces electron excess in the quantum-dot layer 33, and reduces a decrease in light emission efficiency or a progress in deactivation of the quantum dots.

Furthermore, the quantum dots contained in the first quantum dot layer 331 exhibits a higher advantageous effect of the shells protecting the cores than the quantum dots contained in the second quantum dot layer 332. Hence, the first quantum-dot layer 331 is higher in hole concentration than the second quantum-dot layer 332, and the quantum-dot layer 33 according to this embodiment can make the quantum dots contained in the first quantum-dot layer 331 less likely to be deactivated than the quantum dots contained in the second quantum-dot layer 332. Thus, each of the light-emitting elements of the display device 1 according to this embodiment can reduce progress in deactivation of the quantum dots in the first quantum-dot layer 331 and increase emission efficiency of the quantum-dot layer 33 as a whole.

In particular, in the first quantum-dot layer 331, the thickness T3 of the first shell S1 with a narrower bandgap is made greater than the thickness T4 of the second shell S2. As a result, the shell of each of the quantum dots is formed thick. Thanks to such a feature, the first quantum-dot layer 331 can reduce a decrease in efficiency in injecting the carriers into the quantum dots, the decrease being caused by an increase in thickness of the shell of each of the quantum dots in the first quantum-dot layer 331.

In this embodiment, as well, in the quantum-dot layer 33 of each of the light-emitting elements of the display device 1, at least a portion of the composition of the quantum-dot layer 33 around the core of each of the quantum dots has a concentration gradient in a direction from toward a center of the core to toward around the core. Hence, in this embodiment, as well, the light-emitting element of the display device 1 can reduce density of dangling bonds around the cores of the quantum dots contained in the quantum-dot layer 33, and increase design flexibility around the cores.

The display device 1 according to this embodiment may be produced, with partially changing the steps of producing the display device 1 according to the previous embodiment described above.

For example, in the method for producing the display device 1 according to this embodiment, Step S5 to Step S8 for synthesizing a quantum dot material may be repeated to synthesize two materials; that is, the material of the first quantum-dot layer 331 and the material of the second quantum-dot layer 332. In particular, in this embodiment, at the step of synthesizing the material of the quantum-dot layer 331, Step S6 may take a long time period for the growth of the first shell S1 on the core C, so that the first shell S1 may be synthesized to have a greater thickness.

Furthermore, in the method for producing the display device 1 according to this embodiment, the first quantum-dot layer 331 and the second quantum-dot layer 332 may be separately formed at Step S9 and Step S10. In other words, for example, the material of the first quantum-dot layer 331 may be applied and heated, and, after that, the material of the second quantum-dot layer 332 may be applied and heated. Thanks to such a feature, the quantum dots in the already-formed first quantum-dot layer 331 can be kept from deteriorating by the heat applied to the material of the second quantum-dot layer 332.

### Third Embodiment

### Reduction in Electron Excess Due to Difference in Shell Bandgap

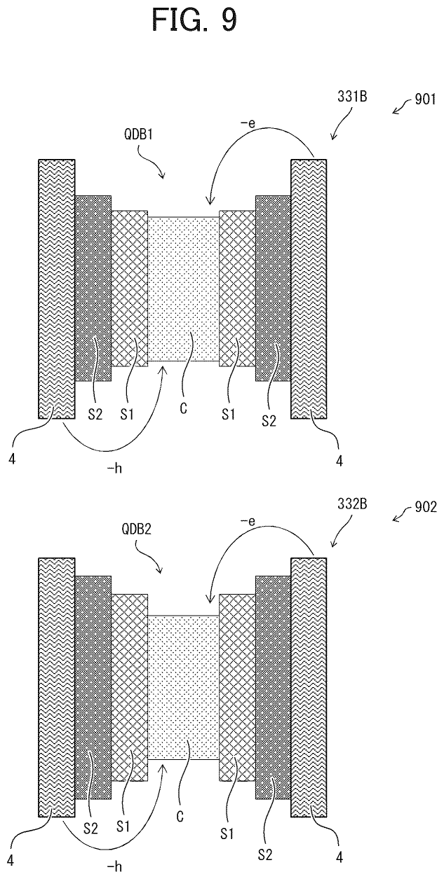

Next, with reference to FIG. 9, a configuration of the display device 1 according to another embodiment will be described. The display device 1 according to this embodiment may be the same in configuration as the display device 1 according to the previous embodiment, except for a bandgap between the shell of a quantum dot contained in the first quantum-dot layer 331 and the shell of a quantum dot contained in the second quantum-dot layer 332.

FIG. 9 illustrates band diagrams each showing an exemplary bandgap of each of the portions of the blue quantum-dot layer 33B according to this embodiment. A band diagram 901 of FIG. 9 indicates bandgaps between: the core C, the first shell S1, and the second shell S2 of one of the first blue quantum dots QDB1; and the inorganic filler material 4 around each of the quantum dots. A band diagram 902 of FIG. 9 indicates bandgaps between: the core C, the first shell S1, and the second shell S2 of one of the second blue quantum dots QDB2; and the inorganic filler material 4 around each of the quantum dots.

As illustrated in the band diagram 901 and the band diagram 902, in this embodiment, the bandgap of the first shell S1 of the first blue quantum dot QDB1 is narrower than the bandgap of the first shell S1 of the second blue quantum dot QDB2. Furthermore, in this embodiment, the bandgap of the second shell S2 of the first blue quantum dot QDB1 is narrower than the bandgap of the second shell S2 of the second blue quantum dot QDB2. In other words, in this embodiment, the bandgap of the shell of a quantum dot contained in the first blue quantum-dot layer 331B is narrower than the bandgap of the shell of a quantum dot contained in the second blue quantum-dot layer 332B.

Note that, as to the quantum dots contained in the quantum-dot layer 33 according to this embodiment, the shells of the quantum dots are approximately the same in thickness between the first quantum-dot layer 331 and the second quantum-dot layer 332. For example, as to the quantum dots in the first quantum-dot layer 331 and the second quantum-dot layer 332, the first shell S1 and the second shell S2 of each of the quantum dots may respectively have the thickness T1 and the thickness T2.

Whereas, as to the quantum dots contained in the quantum-dot layer 33 according to this embodiment, the shells of the quantum dots may be different in thickness between the first quantum-dot layer 331 and the second quantum-dot layer 332. For example, as to the quantum dots in the first quantum-dot layer 331, the first shells S1 may have the thickness T3 and the second shells S2 may have the thickness T4. Furthermore, as to the quantum dots in the second quantum-dot layer 332, the first shells S1 may have the thickness T5 and the second shells S2 may have the thickness T6.

Hence, a barrier against injection of the carriers into the quantum dots contained in the first quantum-dot layer 331 is lower than a barrier against injection of the carriers into the quantum dots contained in the second quantum-dot layer 332. Hence, efficiency in injecting the carriers into the quantum dots contained in the first quantum-dot layer 331 is higher than efficiency in injecting the carriers into the quantum dots contained in the second quantum-dot layer 332. Hence, because of the same reason as that described in the previous embodiment, each of the light-emitting elements of the display device 1 according to this embodiment reduces electron excess in the quantum-dot layer 33, and reduces a decrease in light emission efficiency or a progress in deactivation of the quantum dots.

In this embodiment, as well, in the quantum-dot layer 33 of each of the light-emitting elements of the display device 1, at least a portion of the composition of the quantum-dot layer 33 around the core of each of the quantum dots has a concentration gradient in a direction from toward a center of the core to toward around the core. Hence, in this embodiment, as well, the light-emitting element of the display device 1 can reduce density of dangling bonds around the cores of the quantum dots contained in the quantum-dot layer 33, and increase design flexibility around the cores.

The display device 1 according to this embodiment may be produced, with partially changing the steps of producing the display device 1 according to the previous embodiment described above. For example, in the method for producing the display device 1 according to this embodiment, the quantum dots to be contained in the first quantum-dot layer 331 may be synthesized, with changes made to the materials used at Step S6 and Step S7 of the step of synthesizing the materials of the first quantum-dot layer 331.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A light-emitting element, comprising:
a first electrode;
a second electrode; and
a quantum-dot layer positioned between the first electrode and the second electrode, and containing a plurality of quantum dots including at least cores, and an inorganic filler material filling spaces between the plurality of quantum dots, at least a portion of a composition of the quantum-dot layer around at least one of the cores having a concentration gradient in a direction from toward a center of the at least one core to toward around the core.

2. The light-emitting element according to claim 1,
wherein at least a portion included in at least one of the quantum dots and provided around the core has a bandgap wider toward the center of the core than toward around the core.

3. The light-emitting element according to claim 1,
wherein at least one of the quantum dots further includes a shell positioned at least partially around the core, and at least a portion of a composition of the shell has a concentration gradient from toward the center of the core to toward around the core.

4. The light-emitting element according to claim 3,
wherein the shell has: a first shell positioned at least partially around the core, and containing a first shell material; and a second shell positioned at least partially around the first shell, and containing a second shell material having at least a portion of an element of the first shell material.

5. The light-emitting element according to claim 4,
wherein x, y, z are real numbers satisfying 0≤x<y<z≤1, and A, B, and C are elements that are different from one another,
the first shell contains AₓB₁₋ₓC,
the second shell contains A_{y}B_{1-y}C, and
the inorganic filler material contains A_{z}B_{1-z}C.

6. The light-emitting element according to claim 5,
wherein the x, the y, and the z satisfy y−x>0.04 and z−y>0.04.

7. The light-emitting element according to claim 5,
wherein the x, the y, and the z satisfy 0.7x+0.3z<y<0.3x+0.7z.

8. The light-emitting element according to claim 4,
wherein a thickness of the first shell is 0.5 nm or more and 2.5 nm or less, and a thickness of the second shell is 0.5 nm or more and 2.5 nm or less.

9. The light-emitting element according to claim 3,
wherein the first electrode is an anode, and the second electrode is a cathode, and
the quantum-dot layer includes: a first quantum-dot layer; and a second quantum-dot layer provided toward the cathode with respect to the first quantum-dot layer.

10. The light-emitting element according to claim 9,
wherein the shell of the at least one of the quantum dots in the first quantum-dot layer is at least partially thicker than the shell of the at least one of the quantum dots in the second quantum-dot layer.

11. The light-emitting element according to claim 9,
wherein a bandgap of the shell of the at least one of the quantum dots in the first quantum-dot layer is at least partially narrower than a bandgap of the shell of the at least one of the quantum dots in the second quantum-dot layer.

12. The light-emitting element according to claim 1,
wherein, in the quantum-dot layer, at least a portion of a composition of the inorganic filler material has a concentration gradient in a direction from toward the at least one core to toward around the core.

13. The light-emitting element according to claim 1,
wherein the inorganic filler material contains zinc magnesium sulfide.

14. The light-emitting element according to claim 1,
wherein the inorganic filler material contains zinc selenium sulfide.

15. A display device, comprising:
a substrate; and a plurality of light-emitting elements above the substrate,
wherein at least one of the plurality of light-emitting elements is the light-emitting element according to claim 1.

16. A method for producing a light-emitting element including: a first electrode; a second electrode; and a quantum-dot layer positioned between the first electrode and the second electrode, and containing a plurality of quantum dots including at least cores, and an inorganic filler material filling spaces between the plurality of quantum dots, the method comprising:
a synthesizing step of synthesizing the quantum dots;
a forming step of forming the quantum-dot layer containing the inorganic filler material and the quantum dots synthesized at the synthesizing step; and at least one of
a first step of synthesizing the quantum dots at the synthesizing step, the quantum dots each including one of the cores and a shell positioned partially around the one core, and at least a portion of a composition of the shell having a concentration gradient from toward a center of the core to toward around the core, or
a second step of forming the quantum-dot layer at the forming step, at least a portion of a composition of the inorganic filler material having a concentration gradient from toward the center of at least one of the cores to toward around the core.

17. The method for producing the light-emitting element according to claim 16, comprising
at least the first step,
wherein the first step includes: a first shell synthesizing step of synthesizing a first shell positioned at least partially around the core, and containing a first shell material; and a second shell synthesizing step of synthesizing a second shell positioned at least partially around the first shell, and containing a second shell material containing at least a portion of an element of the first shell material.

18. The method for producing the light-emitting element according to claim 17,
wherein x, y, z are real numbers satisfying 0≤x<y<z≤1, and A, B, and C are elements that are different from one another,
at the first shell synthesizing step, the first shell is synthesized to contain AₓB₁₋ₓC in the first shell material,
at the second shell synthesizing step, the second shell is synthesized to contain A_{y}B_{1-y}C, in the second shell material, and
at the forming step, the quantum-dot layer is formed to contain the quantum dots and the inorganic filler material containing A_{z}B_{1-z}C.

19. A light-emitting element produced by the method according to claim 18.

20. (canceled)

21. A light-emitting element, comprising:
a first electrode;
a second electrode; and
a quantum-dot layer positioned between the first electrode and the second electrode, and containing a plurality of quantum dots including at least cores, and an inorganic filler material filling spaces between the plurality of quantum dots, at least a portion of a composition of the quantum-dot layer around at least one of the cores having a concentration gradient, leading to the inorganic filler material, in a direction from toward a center of the at least one core to toward around the core.
